(19) United States
(12) Patent Application Publication
(10) Pub. No.: US 2025/0286550 A1
(43) Pub. Date: Sep. 11, 2025

(54) TRANSISTOR SHUTDOWN CIRCUT

(71) Applicant: Texas Instruments Incorporated, Dallas, TX (US)

(72) Inventors: Bikash PRADHAN, Bangalore (IN); Dattatreya BARAGUR SURYANARAYANA, Bangalore (IN); Ramakrishna ANKAMREDDI, Bangalore (IN); Yash SHAH, Mumbai (IN)

(73) Assignee: Texas Instruments Incorporated, Dallas, TX (US)

(21) Appl. No.: 18/673,472

(22) Filed: May 24, 2024

Related U.S. Application Data
(60) Provisional application No. 63/562,518, filed on Mar. 7, 2024.

(51) Int. Cl. H03K 17/30; H02M 3/158

(52) U.S. Cl. CPC H03K 17/302; H02M 3/1586

(57) ABSTRACT

A circuit includes a first transistor, a second transistor, a third transistor, and a fourth transistor. The first transistor has a first terminal, a second terminal, and a control terminal. The second transistor has a first terminal coupled to the control terminal of the first transistor, a second terminal coupled to the second terminal of the first transistor, and a control terminal. The third transistor has a first terminal coupled to the control terminal of the first transistor, a second terminal coupled to the control terminal of the second transistor, and a control terminal. The fourth transistor has a first terminal configured to receive a drive voltage, a second terminal coupled to the control terminal of the third transistor, and a control terminal coupled to the first terminal of the fourth transistor.

### CROSS-REFERENCE TO RELATED APPLICATIONS

This application claims priority to U.S. Provisional Application No. 63/562,518, filed Mar. 7, 2024, entitled “Low IQ and Low Area Shut Down Scheme for Deterministic FET Power-Off in Switching Regulator Applications”, which is hereby incorporated herein by reference in its entirety.

### BACKGROUND

A switch can be used to control the flow of current from a voltage source to a load circuit. A transistor can be used to implement such as switch. A circuit using a transistor as a switch may include a gate driver to control the transistor. The gate driver provides a control signal tor turning the transistor on and off.

### SUMMARY

In one example, a circuit includes a drive control circuit and a threshold circuit. The drive control circuit has a first terminal configured to provide a transistor control signal, and a second terminal configured to receive a transistor reference signal. The drive control circuit includes a first transistor and a second transistor. The first transistor has a first terminal coupled to the first terminal of the drive control circuit, a second terminal coupled to the second terminal of the drive control circuit, and a control terminal. The second transistor has a first terminal coupled to the first terminal of the first transistor, a second terminal coupled to the control terminal of the first transistor, and a control terminal. The threshold circuit has a first terminal configured to receive a drive voltage. The threshold circuit includes a third transistor having a first terminal coupled to the first terminal of the threshold circuit, a second terminal coupled to the control terminal of the second transistor, and a control terminal coupled to the first terminal of the third transistor.

In another example, a circuit includes a first transistor, a second transistor, a third transistor, and a fourth transistor. The first transistor has a first terminal, a second terminal, and a control terminal. The second transistor has a first terminal coupled to the control terminal of the first transistor, a second terminal coupled to the second terminal of the first transistor, and a control terminal. The third transistor has a first terminal coupled to the control terminal of the first transistor, a second terminal coupled to the control terminal of the second transistor, and a control terminal. The fourth transistor has a first terminal configured to receive a drive voltage, a second terminal coupled to the control terminal of the third transistor, and a control terminal coupled to the first terminal of the fourth transistor.

In a further example, a circuit includes a transistor, a driver circuit, and a transistor control circuit. The transistor has a first terminal, a second terminal, and a control terminal. The driver circuit has an output coupled to the control terminal of the transistor, an input configured to receive a drive signal, and a terminal configured to receive a drive voltage. The transistor control circuit has a first terminal coupled to the control terminal of the transistor, a second terminal coupled to the second terminal of the transistor, and a third terminal coupled to the terminal of the driver circuit. The transistor control circuit is configured to conduct current between the control terminal of the transistor and the second terminal of the transistor responsive to the drive voltage being less than a threshold.

### BRIEF DESCRIPTION OF THE DRAWINGS

FIG. 1 is a block diagram of an example transistor circuit that includes a transistor control circuit.

FIG. 2 is a schematic diagram of an example transistor control circuit suitable for use in the transistor circuit of FIG. 1.

FIG. 3 is a graph of example signals in the transistor control circuit of FIG. 2.

FIG. 4 is a block diagram of an example multi-phase switching converter that includes the transistor control circuit of FIG. 2.

FIG. 5 is a block diagram of an example circuit that includes a high-side switch using the transistor control circuit of FIG. 2.

### DETAILED DESCRIPTION

A transistor (e.g., a metal oxide semiconductor field effect transistor (MOSFET)) can be used as a switch in some applications, with gate driver circuitry to turn the transistor on and off. If the power supply voltage provided to the gate driver circuitry is insufficient to properly power the gate driver circuitry, then the transistor may be improperly controlled. For example, the gate of a MOSFET may be left floating, and the transistor may be inadvertently turned on by transients caused by circuits coupled to the transistor. Such uncontrolled turn-on of the transistor can result in the flow of currents that may damage the transistor or circuits coupled to the transistor. The transistor control circuits described herein prevent unintended turn on the transistor if the driver circuitry is not properly powered. Accordingly, the transistor control circuits can prevent damage to the transistor or other circuits caused by uncontrolled current flow.

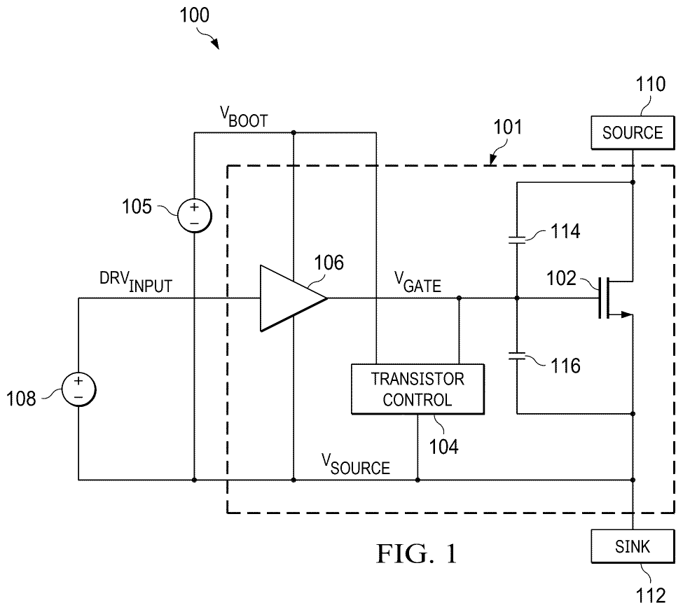

FIG. 1 is a block diagram of an example circuit 100 that includes transistor shutdown based on gate driver supply voltage. The circuit 100 includes a transistor circuit 101, a voltage source circuit 110, a current sink circuit 112, a boot voltage source 105, and a drive signal source 108. The transistor circuit 101 includes a transistor 102, a transistor control circuit 104, and a driver circuit 106. The transistor 102 conducts current from the voltage source circuit 110 to the current sink circuit 112 if the transistor 102 is turned on. The transistor 102 may be an n-channel field effect transistor (NFET) is some examples of the transistor circuit 101. The transistor 102 has a first terminal (e.g., drain) coupled to an output of the voltage source circuit 110, a second terminal (e.g., source) coupled to an input of the current sink circuit 112, and a control terminal (e.g., gate). Gate-to-drain capacitance of the transistor 102 is shown as capacitor 114, and gate-to-source capacitance of the transistor 102 is shown as capacitor 116. The voltage source circuit 110 may be a battery, a battery pack, a power supply, or other circuit that provides an output voltage. The current sink circuit 112 may be power supply circuitry, an application circuit, or other circuit that sinks current from the voltage source circuit 110 through the transistor 102.

The driver circuit 106 controls the transistor 102. The driver circuit 106 has an input coupled to an output of the drive signal source 108, and an output coupled to the control terminal of the transistor 102. The driver circuit 106 receives a driver input signal (DRV_{INPUT}) from the drive signal source 108, and provides the drive signal (V_{GATE}) to the control terminal of the transistor 102 with voltage and current suitable for proper operation of the transistor 102. A power terminal of the driver circuit 106 is coupled to an output of the boot voltage source 105 for receipt of voltage (V_{BOOT}) that powers the driver circuit 106. A reference terminal of the driver circuit 106 is coupled to the second terminal of the transistor 102 for receipt of reference voltage (V_{SOURCE}). The boot voltage source 105 may be a charge pump, a fly-back converter, or other circuit that generates voltage for driving the transistor 102. The drive signal source 108 may be a pulse width modulation circuit or other circuit that generates a signal for controlling the transistor 102.

If the voltage powering the driver circuit 106 (V_{BOOT}) is insufficient to properly power the circuitry of the driver circuit 106, then the output of the driver circuit 106 may have high-impedance, and the control terminal of the transistor 102 is left floating. With the control terminal of the transistor 102 floating, the transistor 102 can be turned on through the capacitor 114 or the capacitor 116 by transients caused by the voltage source circuit 110 or the current sink circuit 112. Inadvertent turn on the transistor 102 can result in large current flow through the transistor 102 that can damage the transistor 102, the voltage source circuit 110, or the current sink circuit 112.

The transistor control circuit 104 prevents unintended turn on the transistor 102 if the driver circuit 106 is not properly powered. The transistor control circuit 104 has a terminal coupled to the power terminal of the driver circuit 106, a terminal coupled to the reference terminal of the driver circuit 106, and a terminal coupled to the control terminal of the transistor 102. The transistor control circuit 104 conducts current from the control terminal of the transistor 102 to the second terminal of the transistor 102 to turn off the transistor 102 if V_{BOOT} is too low to properly power the circuitry of the driver circuit 106 (e.g., less than 1 volt). If V_{BOOT} is high enough to properly power the circuitry of the driver circuit 106 (e.g., greater than 1 volt), then the transistor control circuit 104 releases the control terminal of the transistor 102 to be controlled by the driver circuit 106.

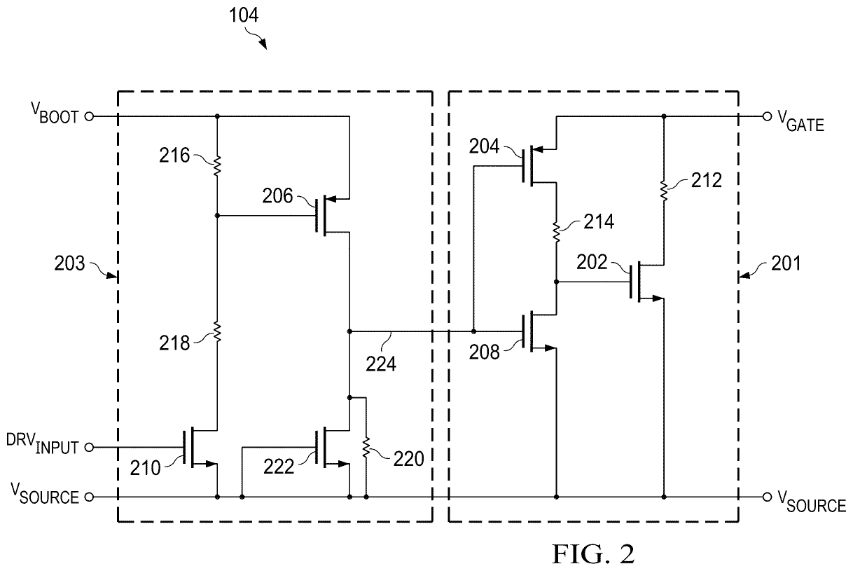

FIG. 2 is a schematic diagram of an example transistor control circuit 104. The transistor control circuit 104 includes a drive control circuit 201 and a threshold circuit 203. The threshold circuit 203 has a first terminal coupled to the power terminal of the driver circuit 106 for receipt of V_{BOOT}, a second terminal coupled to the reference terminal of the driver circuit 106 for receipt of V_{SOURCE}, an input coupled to the input of the driver circuit 106 for receipt of DRV_{INPUT}, and an output for providing a control signal 224 to the drive control circuit 201. The threshold circuit 203 provides the control signal 224 with a first voltage (e.g., less than the threshold voltage of the transistor 208) to activate the drive control circuit 201. Activating the drive control circuit 201 causes the drive control circuit 201 to conduct current from the control terminal of the transistor 102 to the second terminal of the transistor 102. The drive control circuit 201 provides the control signal 224 with a second voltage (e.g., greater than the threshold voltage of the transistor 208) to deactivate the drive control circuit 201. Deactivating the drive control circuit 201 causes the drive control circuit 201 to disconnect the control terminal of the transistor 102 from the second terminal of the transistor 102, which allows the driver circuit 106 to control the transistor 102.

The threshold circuit 203 includes a transistor 206, a transistor 210, a resistor 216, a resistor 218, and a resistor 220. The threshold circuit 203 may also include a transistor 222. The transistor 210 and the transistor 222 may be NFETs. The transistor 206 may be a p-channel field effect transistor (PFET). If V_{BOOT} is less than a threshold (e.g., less than 1 volt), then the threshold circuit 203 provides the control signal 224 with the first voltage, to activate the drive control circuit 201. If V_{BOOT} is greater than the threshold (e.g., greater than 1 volt), then the threshold circuit 203 provides the control signal 224 with the second voltage, to deactivate the drive control circuit 201.

The transistor 206 has a first terminal (e.g., source) coupled to the first terminal of the threshold circuit 203, a second terminal coupled to the drive control circuit 201, and a control terminal coupled to the first terminal of the transistor 206 via the resistor 216. A first terminal of the resistor 216 is coupled to the control terminal of the transistor 206 and a second terminal of the resistor 216 is coupled to the first terminal of the transistor 206. The resistor 220 has a first terminal coupled to the second terminal of the transistor 206, and a second terminal coupled to the second terminal of the threshold circuit 203. The transistor 210 has a first terminal (e.g., drain) coupled to the control terminal of the transistor 206 via the resistor 218, a second terminal coupled to the second terminal of the threshold circuit 203, and a control terminal coupled to the input of the threshold circuit 203 and the input of the driver circuit 106.

If the voltage of DRV_{INPUT} received at the control terminal of the transistor 210 is too low to turn on the transistor 210 (e.g., DRV_{INPUT} has logic low state), then the transistor 206 is turned off, and the resistor 220 pulls the control signal 224 output by the threshold circuit 203 down to activate the drive control circuit 201. The value of V_{BOOT} needed to turn on the transistor 206 is determined by the resistors 216, 218, and 220, and the transistor 206, various combinations of which may be selected to provide a desired threshold voltage. If the voltage of DRV_{INPUT} is sufficient to turn on the transistor 210, then current flows through the resistor 216 and the resistor 218, and the voltage at the control terminal of the transistor 206 falls. If the voltage at the control terminal of the transistor 206 causes the transistor 206 to turn on, then current flows through the transistor 206 and the resistor 220, and a voltage is developed across the resistor 220 to provide the control signal 224 with the second voltage.

The transistor 222 may be coupled in parallel with the resistor 220 between the second terminal of the transistor 206 and the second terminal of the threshold circuit 203. The transistor 222 has a first terminal (e.g., drain coupled to the second terminal of the transistor 206, a second terminal (e.g., source) coupled to the second terminal of the threshold circuit 203, and a control terminal (e.g., gate) coupled to the second terminal of the threshold circuit 203. The transistor 222 is biased off, and the body diode of the transistor 222 is coupled between the second terminal of the transistor 206 and the second terminal of the threshold circuit 203 for electrostatic discharge protection.

The drive control circuit 201 has a first terminal coupled to the control terminal of the transistor 102, and a second terminal coupled to the second terminal of the transistor 102. The drive control circuit 201 includes a transistor 202, a transistor 204, a transistor 208, a resistor 212, and a resistor 214. The transistor 202 and the transistor 208 may be NFETs, and the transistor 204 may be a PFET. The transistor 202 has a first terminal (e.g., drain) coupled to the first terminal of the drive control circuit 201 (and the control terminal of the transistor 102) via the resistor 212, a second terminal (e.g., source) coupled to the second terminal of the drive control circuit 201 (and the second terminal of the transistor 102), and control terminal (e.g., gate). A first terminal of the resistor 212 is coupled to the first terminal of the transistor 202 (for providing V_{GATE}), and a second terminal of the resistor 212 is coupled to the first terminal of the drive control circuit 201. The transistor 204 has a first terminal (e.g., source) coupled to the second terminal of the resistor 212, a second terminal (e.g., drain) coupled to the control terminal of the resistor 212 via the resistor 214, and control terminal (e.g., gate) coupled to the output of the threshold circuit 203. The resistor 214 has a first terminal coupled to the second terminal of the transistor 204, and a second terminal coupled to the control terminal of the transistor 202. If the transistor 204 is turned on, then the transistor 202 is diode-connected between the control terminal of the transistor 102 and the second terminal of the transistor 102, and can conduct current from the control terminal of the transistor 102 to the second terminal of the transistor 102. Thus, the control terminal of the transistor 102 is pulled-down by the transistor control circuit 104 if the control signal 224 has the first voltage.

The transistor 208 has a first terminal (e.g., drain) coupled to the control terminal of the transistor 202, a second terminal (e.g., source) coupled to the second terminal of the transistor 202, and a control terminal (e.g., gate) coupled to the control terminal of the transistor 204. If the control signal 224 provided by the threshold circuit 203 has the first voltage, then the transistor 204 is turned on and the transistor 208 is turned off to diode-connect the transistor 202, and turn off the transistor 102. If the control signal 224 provided by the threshold circuit 203 has the second voltage, then transistor 208 is turned on, and the transistors 208 and 202 are turned off to allow the driver circuit 106 to control the transistor 102.

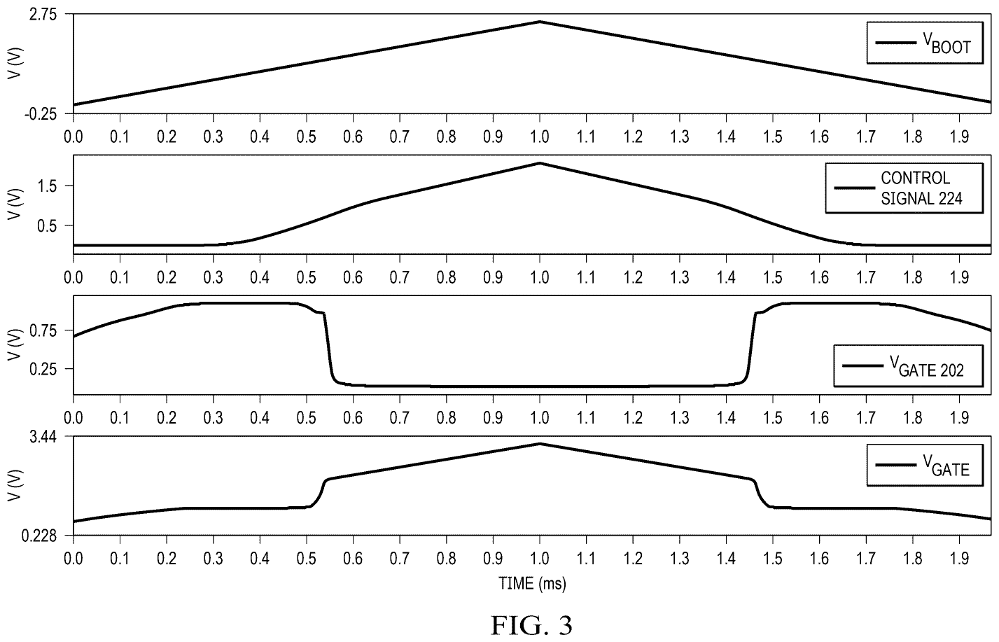

FIG. 3 is a graph of example signals in the transistor circuit 101. FIG. 3 shows the drive voltage V_{BOOT} that powers the driver circuit 106, the control signal 224 provided by the threshold circuit 203, voltage at the control terminal of the transistor 202 (V_{GATE202}), and voltage at the control terminal of the transistor 102 (V_{GATE}). V_{BOOT} is shown ramping from about zero volts to about 2.75 volts and back to about zero volts to illustrate operation of the transistor control circuit 104 with changing V_{BOOT}. At time zero of the graph, the transistor 202 is off, the transistor 208 is off, the transistor 204 is on, and the transistor 206 is on. Accordingly, the transistor 202 is diode-connected through the transistor 204 and the resistor 214, and the transistor 102 is turned off. As the voltage of V_{BOOT} increases, the transistor 206 turns on, and the voltage across the resistor 220 (voltage of the control signal 224) increases. When the control signal 224 exceeds the threshold voltage of the transistor 208, the transistor 208 turns on, the transistor 204 turns off, and V_{GATE202} falls to turn off the transistor 202. With the transistor 202 turned off the driver circuit 106 controls the transistor 102, and V_{GATE} rises and follows V_{BOOT} to turn on the transistor 102.

As V_{BOOT} falls from about 2.75 volts back to about zero volts, the control signal 224 falls. When the control signal 224 is less than the threshold voltage of the transistor 208, the transistor 208 turns off the transistor 204 turns on, and V_{GATE202} rises to turn on the transistor 202. With the transistor 202 turned on the transistor control circuit 104 controls the transistor 102, and V_{GATE} falls to turn off the transistor 102.

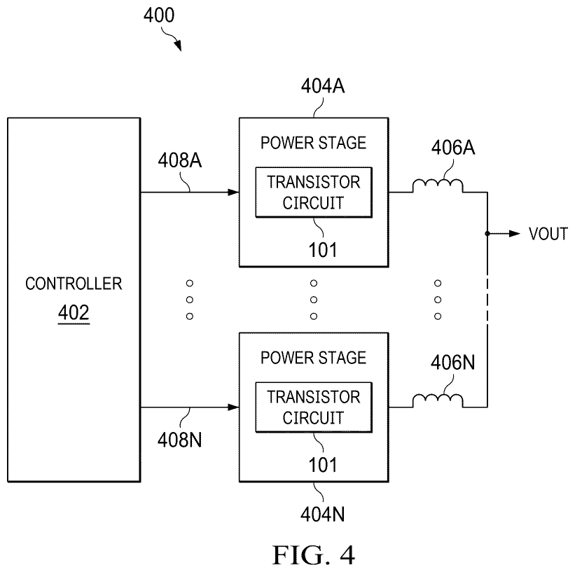

FIG. 4 is a block diagram of an example multi-phase switching converter 400 that includes transistor shutdown based on gate driver supply voltage. The multi-phase switching converter 400 includes a controller 402, power stages 404A through 404N, and inductors 406A through 406N. “N” denotes the total number of power stages included in the multi-phase switching converter 400. Each of the power stages 404A through 404N is coupled to an output of the controller 402. The controller 402 is an example of the drive signal source 108, and generates the drive signals 408A through 408N. A first terminal of each inductor 406A through 4066N is coupled to an output of one of the power stages 404A through 404N. The second terminals of the inductors 406A through 406N are connected to provide the output voltage VOUT for powering a load circuit.

Each of the power stages 404A through 404N includes an example of the transistor circuit 101. In an implementation of the multi-phase switching converter 400, the transistor circuit 101 may be provided as a high-side switching circuit of a buck converter. Each power stage 404A through 404N may include low-side switching circuitry that has been omitted from FIG. 4 in the interest of clarity. The transistor circuit 101 includes the transistor 102, the transistor control circuit 104 and the driver circuit 106. Considering the power stage 404A, the input of the driver circuit 106 receives the drive signal 408A, and drives the drive signal 408A to the transistor 102.

As explained with regard to FIG. 2, the transistor control circuit 104 controls the transistor 102 if the drive voltage powering the driver circuit 106 is below a threshold (e.g., 1 volt). The transistor control circuit 104 prevents the transistor 102 from turning on inadvertently if the driver circuit 106 is unable to control the transistor 102. By preventing inadvertent turn-on of the transistor 102, the transistor control circuit 104 prevents the flow of large currents through transistor 102 that may damage the transistor 102 or components coupled to the transistor 102. When the drive voltage is high enough to properly power the driver circuit 106 (e.g., greater than 1 volt), the transistor control circuit 104 relinquishes control of the transistor 102 to the driver circuit 106.

Each of the power stages 404A through 404N may also include a low-side transistor (e.g., an NFET) coupled to the transistor circuit 101 as the current sink circuit 112 (shown in FIG. 1). For example, a drain of the low-side transistor may be coupled to V_{SOURCE}, a source of the low-side transistor may be coupled to ground, and a gate of the low-side transistor may be coupled to an output of a low-side transistor driver circuit (not shown). The low-side transistors have been omitted from the power stages 404A through 404N in the interest of clarity.

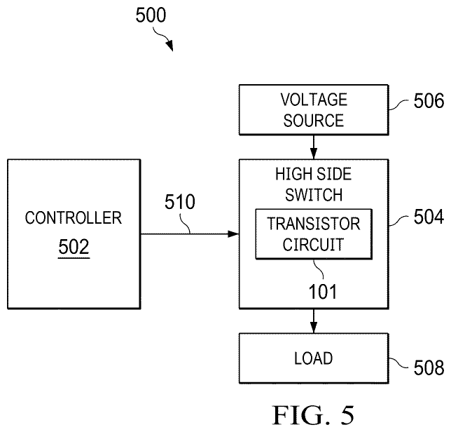

FIG. 5 is a block diagram of an example circuit 500 that includes a high-side switching. The circuit 500 includes a controller 502, a high-side switch circuit 504, a voltage source 506, and a load circuit 508. The high-side switch circuit 504 is coupled to the controller 502, the voltage source 506, and the load circuit 508. The controller 502 provides a control signal 510 for controlling the high-side switch circuit 504. The controller 502 is an example of the drive signal source 108. The high-side switch circuit 504 conducts current from the voltage source 506 to the load circuit 508. The voltage source 506 may be a battery, a power supply, or other device. The load circuit 508 may be any circuit that is powered by the voltage source 506.

The high-side switch circuit 504 includes an example of the transistor circuit 101. As explained with regard to FIG. 2, the transistor circuit 101 includes the transistor 102, the transistor control circuit 104 and the driver circuit 106. The transistor 102 conducts current from the voltage source 506 to the load circuit 508. The driver circuit 106 drives the control signal 510 to the transistor 102. The transistor control circuit 104 controls the transistor 102 if the drive voltage powering the driver circuit 106 is below a threshold (e.g., 1 volt). The transistor control circuit 104 prevents the transistor 102 from turning on inadvertently if the driver circuit 106 is unable to control the transistor 102. By preventing inadvertent turn-on of the transistor 102, the transistor control circuit 104 prevents the flow of large currents through transistor 102 that may damage the transistor 102 or the load circuit 508. When the drive voltage is high enough to properly power the driver circuit 106 (e.g., greater than 1 volt), the transistor control circuit 104 relinquishes control of the transistor 102 to the driver circuit 106.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A circuit comprising:
a drive control circuit having a first terminal configured to provide a transistor control signal, and a second terminal configured to receive a transistor reference signal, the drive control circuit including:
a first transistor having a first terminal coupled to the first terminal of the drive control circuit, a second terminal coupled to the second terminal of the drive control circuit, and a control terminal; and
a second transistor having a first terminal coupled to the first terminal of the first transistor, a second terminal coupled to the control terminal of the first transistor, and a control terminal; and
a threshold circuit having a first terminal configured to receive a drive voltage, the threshold circuit including a third transistor having a first terminal coupled to the first terminal of the threshold circuit, a second terminal coupled to the control terminal of the second transistor, and a control terminal coupled to the first terminal of the third transistor.

2. The circuit of claim 1, wherein the drive control circuit includes a fourth transistor having a first terminal coupled to the control terminal of the first transistor, a second terminal coupled to the second terminal of the first transistor, and control terminal coupled to the control terminal of the second transistor.

3. The circuit of claim 1, wherein the drive control circuit includes a resistor having a first terminal coupled to the first terminal of the first transistor and a second terminal coupled to the first terminal of the second transistor.

4. The circuit of claim 1, wherein the drive control circuit includes a resistor having a first terminal coupled to the second terminal of the second transistor and a second terminal coupled to the control terminal of the first transistor.

5. The circuit of claim 1, wherein:
the threshold circuit has a second terminal configured to receive a driver input signal; and
the threshold circuit includes a fourth transistor having a first terminal coupled to the control terminal of the third transistor, a second terminal coupled to the second terminal of the first transistor, and a control terminal coupled to the second terminal of the threshold circuit.

6. The circuit of claim 5, wherein the threshold circuit includes a resistor having a first terminal coupled to the control terminal of the third transistor, and a second terminal coupled to the first terminal of the fourth transistor.

7. The circuit of claim 1, wherein the threshold circuit includes a resistor having a first terminal coupled to the second terminal of the third transistor, and a second terminal coupled to the second terminal of the first transistor.

8. The circuit of claim 1, wherein the threshold circuit includes a resistor having a first terminal coupled to the first terminal of the third transistor, and a second terminal coupled to the control terminal of the third transistor.

9. The circuit of claim 1, wherein the threshold circuit includes a fourth transistor having a first terminal coupled to the second terminal of the third transistor, a second terminal coupled to the second terminal of the first transistor, and a control terminal coupled to the second terminal of the fourth transistor.

10. A circuit comprising:
a first transistor having a first terminal, a second terminal, and a control terminal; and
a second transistor having a first terminal coupled to the control terminal of the first transistor, a second terminal coupled to the second terminal of the first transistor, and a control terminal;
a third transistor having a first terminal coupled to the control terminal of the first transistor, a second terminal coupled to the control terminal of the second transistor, and a control terminal; and
a fourth transistor having a first terminal configured to receive a drive voltage, a second terminal coupled to the control terminal of the third transistor, and a control terminal coupled to the first terminal of the fourth transistor.

11. The circuit of claim 10, further comprising a fifth transistor having a first terminal coupled to the control terminal of the second transistor, a second terminal coupled to the second terminal of the second transistor, and control terminal coupled to the control terminal of the third transistor.

12. The circuit of claim 10, further comprising a resistor having a first terminal coupled to the first terminal of the second transistor and a second terminal coupled to the control terminal of the first transistor.

13. The circuit of claim 10, further comprising a resistor having a first terminal coupled to the second terminal of the third transistor and a second terminal coupled to the control terminal of the second transistor.

14. The circuit of claim 10, further comprising a fifth transistor having a first terminal coupled to the control terminal of the fourth transistor, a second terminal coupled to the second terminal of the second transistor, and a control terminal configured to receive a drive signal.

15. The circuit of claim 14, further comprising:
a first resistor having a first terminal coupled to the control terminal of the fourth transistor, and a second terminal coupled to the first terminal of the fifth transistor; and
a second resistor having a first terminal coupled to the first terminal of the fourth transistor, and a second terminal coupled to the control terminal of the fourth transistor.

16. The circuit of claim 10, further comprising a resistor having a first terminal coupled to the second terminal of the fourth transistor, and a second terminal coupled to the second terminal of the second transistor.

17. A circuit comprising:
a transistor having a first terminal, a second terminal, and a control terminal;
a driver circuit having an output coupled to the control terminal of the transistor, an input configured to receive a drive signal, and a terminal configured to receive a drive voltage; and
a transistor control circuit having a first terminal coupled to the control terminal of the transistor, a second terminal coupled to the second terminal of the transistor, and a third terminal coupled to the terminal of the driver circuit, the transistor control circuit configured to conduct current between the control terminal of the transistor and the second terminal of the transistor responsive to the drive voltage being less than a threshold.

18. The circuit of claim 17, wherein the transistor control circuit includes a threshold circuit coupled to the third terminal of the transistor control circuit, the threshold circuit configured to:
provide a control signal having a first voltage responsive the drive voltage being less than the threshold; and
provide the control signal having a second voltage responsive to the drive voltage being greater than the threshold.

19. The circuit of claim 18, wherein the transistor control circuit includes a drive control circuit coupled to the threshold circuit, the drive control circuit configured to conduct current between the control terminal of the transistor and the second terminal of the transistor based on the control signal having the first voltage.

20. The circuit of claim 18, wherein:
the transistor control circuit includes a fourth terminal coupled to the input of the driver circuit; and
the threshold circuit is configured to provide the control signal having the first voltage responsive to the drive signal having a logic low state.
